(19) United States
(12) Patent Application Publication
(10) Pub. No.: US 2024/0072094 A1
(43) Pub. Date: Feb. 29, 2024

(54) CENTRALLY SYMMETRIC VERTICAL TRANSFER GATE

(71) Applicant: CISTA SYSTEM CORP., Grand Cayman (KY)

(72) Inventors: Jingyi BAI, SAN JOSE, CA (US); Bo-Ray LEE, NEW TAIPEI CITY (TW)

(21) Appl. No.: 17/897,975

(22) Filed: Aug. 29, 2022

(51) Int. Cl. H01L 27/146

(52) U.S. Cl. CPC H01L 27/14643; H01L 27/14603; H01L 27/14689

(57) ABSTRACT

This application describes systems and methods related to vertical transfer gates. An example system includes a photodiode region disposed in a substrate, wherein: the photodiode region is configured to accumulate charge photogenerated in the photodiode region in response to incoming light, the photodiode region comprises a top surface and a bottom surface, the top surface being smaller than the bottom surface, the photodiode region comprises at least two doping concentrations, and a first doping concentration of the two doping concentrations that is closer to the top surface is higher than a second doping concentration of the two doping concentrations that is closer to the bottom surface; and a vertical transfer gate in the substrate, wherein: the vertical transfer gate is above the top surface of the photodiode region and is centrally symmetric to the top surface of the photodiode region, and the vertical transfer gate is configured to transfer the photogenerated charge from the photodiode region to a transfer gate.

### TECHNICAL FIELD

The disclosure relates generally to vertical transfer gates in semiconductor devices.

### BACKGROUND

Image sensors rely on a charge transfer process to convert optical signals to electrical signals. For example, image sensors can use photodiodes to convert photos to electrons and collect electrons. An image sensor can typically include a grid of pixels including photodiodes, which capture the light impinged on them and convert the light signals to electrical signals that is transferred through a transfer gate. The transfer gate can transfer the electrons in the photodiodes to a floating diffusion, which can convert electrons to voltage signals. In an ideal world, all charges accumulated in the photodiode due to incoming light should be transferred and readout. However, if the transfer of photogenerated charges is incomplete, there can be an image lag. In addition, instead of being transferred out, some photogenerated charges may be left in the photodiode, causing deterioration in readout information, such as bright-to-dark or dark-to-bright transitions. Moreover, as the pixel size grows, size of the photodiode also grows, and the transfer speed of the charges may not be fast enough. In addition, for indirect time-of-flight (iTOF) applications, charge transfer speed can be crucial, since it affects time resolutions of the iTOF. There is an increasing need for novel designs in the photodiode and the transfer gate to improve charge transfers in image sensors.

### SUMMARY

Various embodiments of this specification may include hardware circuits, systems, methods related to vertical transfer gates.

According to one aspect, an integrated circuit comprises a photodiode region disposed in a substrate, wherein: the photodiode region is configured to accumulate charge photogenerated in the photodiode region in response to incoming light, the photodiode region comprises a top surface and a bottom surface, the top surface being smaller than the bottom surface, the photodiode region comprises at least two doping concentrations, and a first doping concentration of the two doping concentrations that is closer to the top surface is higher than a second doping concentration of the two doping concentrations that is closer to the bottom surface; and a vertical transfer gate in the substrate, wherein: the vertical transfer gate is above the top surface of the photodiode region and is centrally symmetric to the top surface of the photodiode region, and the vertical transfer gate is configured to transfer the photogenerated charge from the photodiode region to a planar transfer gate.

In some embodiments, the vertical transfer gate is centrally symmetric to the bottom surface of the photodiode region.

In some embodiments, the photodiode region comprises a first well and a second well, the first well is closer to the top surface of the photodiode region than the second well, the first well has the first doping concentration, and the second well has the second doping concentration.

In some embodiments, the photodiode region comprises a third well, the third well is closer to the bottom surface of the photodiode region than the first well and the second well, the third well has a third doping concentration, and the third doping concentration is lower than the first doping concentration and the second doping concentration.

In some embodiments, the integrated circuit is an image sensor that includes a pixel, and the bottom surface of the photodiode region is configured to expand to 90% of a unit pixel area of the pixel.

In some embodiments, the vertical transfer gate is centrally symmetric to the unit pixel area of the pixel.

In some embodiments, the substrate is a p-type substrate, and the photodiode region is an n-type region.

In some embodiments, the integrated circuit comprising a p-type well formed between the top surface of the photodiode region and the vertical transfer gate.

In some embodiments, the vertical transfer gate is further configured to transfer the photogenerated charge from the photodiode region to the planar transfer gate located outside of the substrate.

According to another aspect, an integrated circuit comprises: a photodiode region disposed in a substrate, wherein: the photodiode region is configured to accumulate charge photogenerated in the photodiode region in response to incoming light, the photodiode region comprises a top surface, a first well, and a second well, the top surface of the photodiode region comprises a top surface of the first well and a top surface of the second well, the top surface of the first well is surrounded by the top surface of the second well, the second well has a depth that is deeper than a depth of the first well, and the first well has a first doping concentration that is higher than a second doping concentration of the second well; and a vertical transfer gate in the substrate, wherein: the vertical transfer gate is above the top surface of the photodiode region and is centrally symmetric to the top surface of the first well, and the vertical transfer gate is configured to transfer the photogenerated charge from the photodiode region to a transfer gate.

In some embodiments, the vertical transfer gate is centrally symmetric to the top surface of the second well.

In some embodiments, the photodiode region comprises a third well, the top surface of the photodiode region comprises a top surface of the third well, the top surface of the second well is surrounded by the top surface of the third well, and the third well has a third doping concentration that is lower than the second doping concentration.

In some embodiments, the vertical transfer gate is centrally symmetric to the top surface of the third well.

In some embodiments, the integrated circuit is an image sensor that includes a pixel, and the top surface of the third well is configured to expand to 90% of a unit pixel area of the pixel.

In some embodiments, the vertical transfer gate is centrally symmetric to the unit pixel area of the pixel.

In some embodiments, the substrate is a p-type substrate, and the photodiode region is an n-type region.

In some embodiments, the integrated circuit further comprises comprising a p-type well formed between the top surface of the photodiode region and the vertical transfer gate.

In some embodiments, the vertical transfer gate is further configured to transfer the photogenerated image charge from the photodiode region to a planar transfer gate located outside the substrate.

According to another aspect, a method for manufacturing an integrated circuit comprises: creating a first well in a substrate of the integrated circuit using a first mask at a first depth into the substrate; creating a second well in the substrate using a second mask at a second depth into the substrate, wherein the second mask comprises a surface area that is smaller than a surface area of the first mask, and the second depth is shallower than the first depth; and creating a vertical transfer gate into the substrate, wherein the vertical transfer gate is centrally symmetric to a top surface of the first well and a top surface of the second well, and the vertical transfer gate is configured to transfer charge photogenerated in the first well and the second well in response to incoming light.

These and other features of the systems, methods, and hardware devices disclosed, and the methods of operation and functions of the related elements of structure and the combination of parts and economies of manufacture will become more apparent upon consideration of the following description and the appended claims referring to the drawings, which form a part of this specification, where like reference numerals designate corresponding parts in the figures. It is to be understood, however, that the drawings are for illustration and description only and are not intended as a definition of the limits of the invention.

### BRIEF DESCRIPTION OF THE DRAWINGS

FIG. 1A is a schematic of an example image sensor with a transfer gate, according to some embodiments of this specification.

FIG. 1B is a schematic of an example image sensor with a transfer gate and a photodiode of different dosages, according to some embodiments of this specification.

FIG. 1C is a schematic of an example image sensor with a vertical transfer gate, according to some embodiments of this specification.

FIG. 2 is a schematic of an example image sensor with a centrally symmetric vertical transfer gate, according to some embodiments of this specification.

FIG. 3 is a schematic of an example image sensor with a centrally symmetric vertical transfer gate and horizontal gradient doping, according to some embodiments of this specification.

FIG. 4 is a schematic of an example image sensor with a centrally symmetric vertical transfer gate showing from a top view, according to some embodiments of this specification.

FIG. 5 is a schematic of an example image sensor with a centrally symmetric vertical transfer gate and n-type wells showing from a top view, according to some embodiments of this specification.

FIG. 6 is a flowchart of an example method for manufacturing an image sensor with a symmetric vertical transfer gate, according to some embodiments of this specification.

FIG. 7 is a flowchart of an example method for manufacturing an image sensor with a symmetric vertical transfer gate, according to some embodiments of this specification.

### DETAILED DESCRIPTION

The specification is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present specification. Thus, the specification is not limited to the embodiments shown but is to be accorded the widest scope consistent with the principles and features disclosed herein.

Digital cameras, scanners, and other imaging devices often use image sensors, such as charge-coupled device (CCD) image sensors or complementary metal-oxide semiconductor (CMOS) image sensors, to convert optical signals to electrical signals. An image sensor can typically include a grid of pixels including photodiodes, row access circuitry, column access circuitry, and a ramp signal generator. The pixels capture the light impinged on them and convert the light signals to electrical signals. The row access circuitry controls which row of pixels that the sensor will read. The column access circuitry includes column read circuits that read the signals from corresponding columns. The ramp signal generator generates a ramping signal as a global reference signal for column read circuits to record the converted electrical signal.

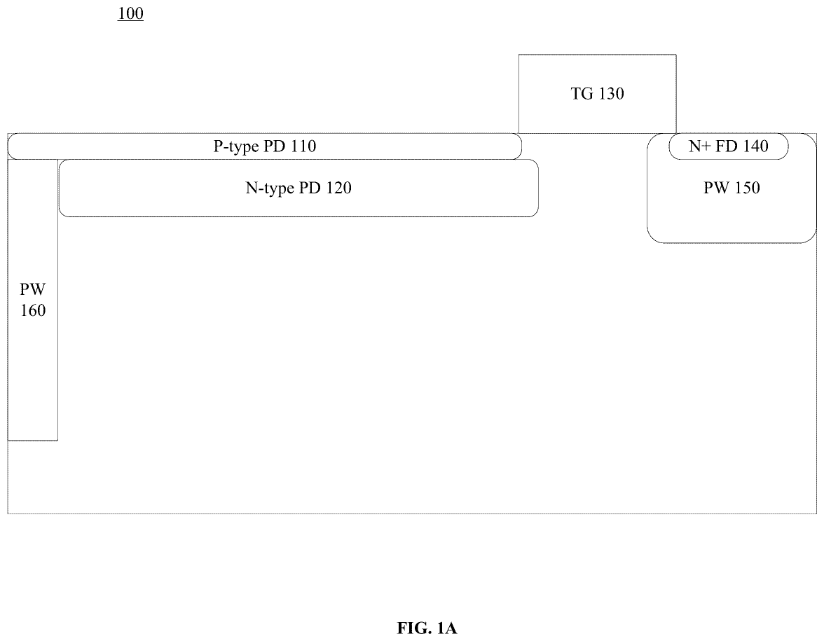

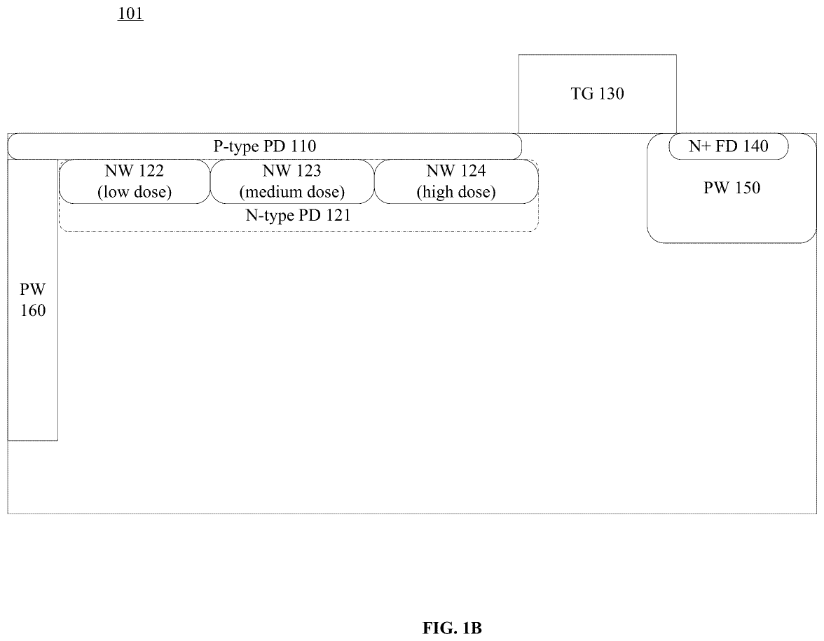

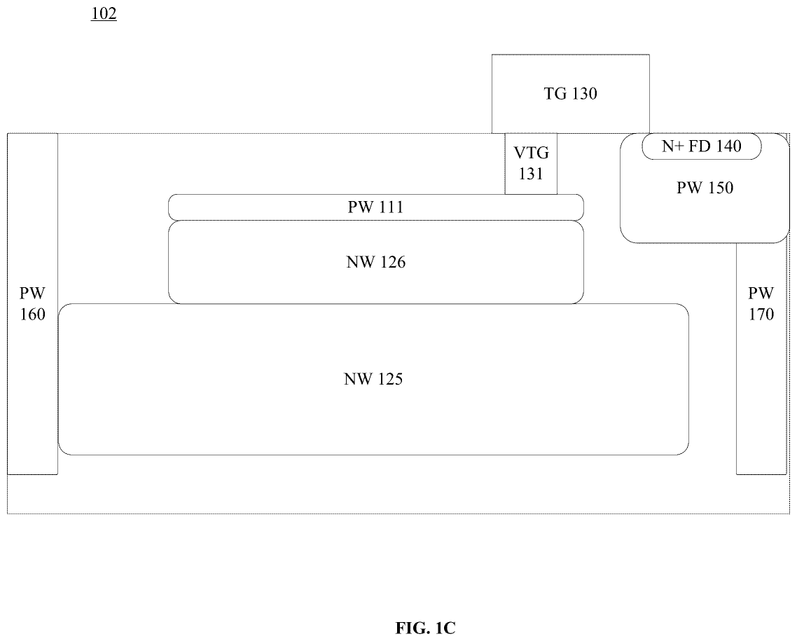

A charge transfer process is one of key performance parameters for image sensors. In an ideal world, all electrons accumulated in the photodiode due to incoming light should be transferred and readout. FIG. 1A is a schematic of an example image sensor with a transfer gate, according to some embodiments of this specification. The schematic in FIG. 1A is for illustrative purposes only, and image sensor 100 shown in FIG. 1A may have fewer, more, and alternative components and connections depending on the implementation.

As shown in FIG. 1A, image sensor 100 comprises a p-type photodiode 110, an n-type photodiode 120, a transfer gate 130, an N+ floating diffusion node 140, and a p-type well 150. In some embodiments, image sensor 100 further comprises a p-type well 160. Incoming light hits image sensor 100 (e.g., from top onto p-type photodiode 110, or from bottom onto n-type photodiode 120), generating photogenerated electrons to flow from n-type photodiode 120. Transfer gate 130 is configured to transfer the photogenerated electrons from n-type photodiode 120 the floating diffusion node 140. If the transfer of the photogenerated electrons is incomplete, there can be an image lag. In addition, instead of being transferred out, some photogenerated electrons may be left in n-type photodiode 120, causing deterioration in readout information, such as bright-to-dark or dark-to-bright transitions. Moreover, as the pixel size grows, size of n-type photodiode 120 also grows, and the transfer speed of electrons from n-type photodiode 120 may not be fast enough. In addition, if the transfer speed is not high enough, frame rates of the image sensor and time resolutions of an iTOF will be affected.

As an improvement, n-type photodiode 120 can comprise different dosages in different sections. FIG. 1B is a schematic of an example image sensor with a transfer gate and a photodiode of different dosages, according to some embodiments of this specification. The schematic in FIG. 1B is for illustrative purposes only, and image sensor 101 shown in FIG. 1 may have fewer, more, and alternative components and connections depending on the implementation.

Similar to image sensor 100, image sensor 101 comprises p-type photodiode 110, transfer gate 130, N+ floating diffusion node 140, and p-type well 150. In addition, image sensor 101 further comprises an n-type photodiode 121, which can be similar to n-type photodiode 120 and configured to enable flowing of generated photogenerated electrons when the incoming light hits image sensor 101 (e.g., from top onto p-type photodiode 110, or from bottom onto n-type photodiode 121). N-type photodiode can comprise different dosages in different regions. For example, as shown in FIG. 1B, n-type photodiode 121 comprises three regions of an n-type well 122 of lower dose, an n-type well 123 of medium dose, and an n-type well 124 of higher dose. In some embodiments, n-type photodiode 121 can comprise other numbers of regions of different dosages, such as two regions or four regions. Due to the dosage difference across different regions, n-type photodiode 121 comprises a gradient doping, which improves charge transfer efficiency. However, diffusion distance can still be long. For example, in large pixels, the diffusion distance can be near 1.414 pitch size. The long diffusion distance can still result in image lags and deterioration in readout information.

As another improvement, a vertical transfer gate can be integrated. FIG. 1C is a schematic of an example image sensor with a vertical transfer gate, according to some embodiments of this specification. The schematic in FIG. 1C is for illustrative purposes only, and image sensor 102 shown in FIG. 1C may have fewer, more, and alternative components and connections depending on the implementation.

Similar to image sensor 100, and image sensor 101, image sensor 102 comprises transfer gate 130, N+ floating diffusion node 140, and p-type well 150. In addition, image sensor 102 further comprises an n-type well 125, an n-type well 126, and a vertical transfer gate 131 located under transfer gate 130 and is communicatively coupled with transfer gate 130 and n-type wells 125 and 126. Vertical transfer gate 131 is configured to transfer the photogenerated electrons from n-type wells 125 and 126 to transfer gate 130. In some embodiments, image sensor 102 further comprises a p-type well 111 located between vertical transfer gate 131 and n-type well 126. P-type well 111 can reduce dark currents generated in vertical transfer gate 131. In some embodiments, p-type well 111 is similar to p-type well 110 in image sensor 100 or image sensor 101. In some embodiments, image sensor 102 further comprises a p-type well 170.

N-type wells 125 and 126 together comprises a higher depth and a large volume than n-type photodiode 120 of image sensor 100 or image sensor 101. As a result, when the incoming light hits image sensor 102 (e.g., from top or from bottom onto n-type photodiode 121), the higher depth and the larger volume of n-type wells 125 and 126 can enhance the flowing of photogenerated electrons, improving charge transfers through vertical transfer gate 131 and transfer gate 130 and resulting in an overall improvement of generated images. However, vertical transfer gate 131 is not located at a center of the pixel (e.g., the center of n-well 126). Since vertical transfer gate 131 is not centrally symmetric, a diffusion distance of charges can still be larger than around 0.707 of the pitch size, resulting in image lags and deterioration in readout information.

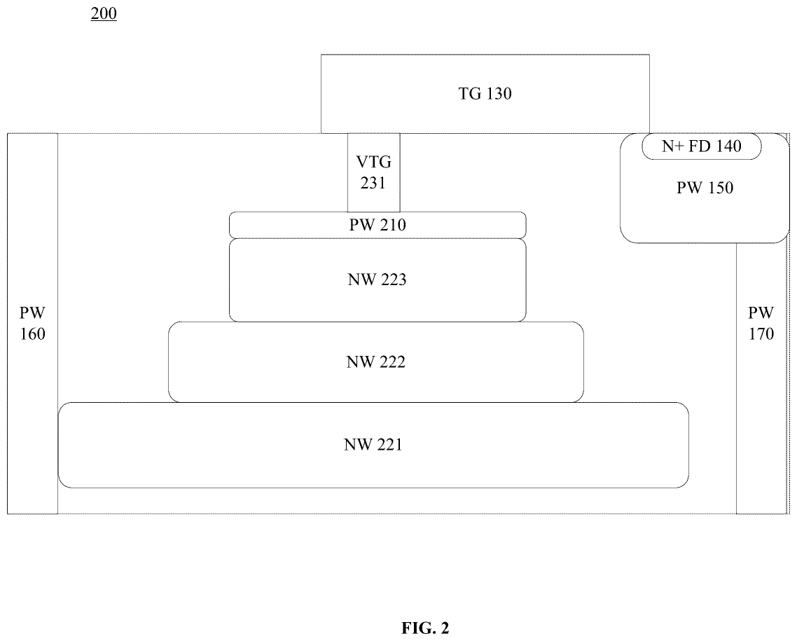

Embodiments of this specification provide systems for improving carrier transfers using vertical transfer gates in an image sensor. FIG. 2 is a schematic of an example image sensor with a centrally symmetric vertical transfer gate, according to some embodiments of this specification. The schematic in FIG. 2 is for illustrative purposes only, and image sensor 200 shown in FIG. 2 may have fewer, more, and alternative components and connections depending on the implementation.

Similar to image sensor 102, image sensor 200 comprises transfer gate 130, N+ floating diffusion node 140, and p-type well 150. In addition, image sensor 200 further comprises an n-type well 221, an n-type well 222, an n-type well 223, and a vertical transfer gate 231 located under transfer gate 130 and is communicatively coupled with transfer gate 130 and n-type wells 221, 222, and 223. In some embodiments, n-type wells 221, 222, and 223 are formed in a semiconductor substrate (e.g., p-type substrate). In some embodiments, vertical transfer gate 231 is located at or near the center of the pixel of image sensor 200 (e.g., centrally symmetric to the pixel of image sensor 200). In some embodiments, image sensor 200 further comprises a p-type well 210 located between vertical transfer gate 231 and n-type well 223. P-type well 210 can reduce dark currents generated in vertical transfer gate 231. In some embodiments, p-type well 210 is similar to p-type well 111 in image sensor 102.

N-type wells 221, 222, and 223 are stacked together. In some embodiments, as shown in FIG. 2, n-type wells 221, 222, and 223 have different surface areas, with n-type well 221 having a larger surface area, n-type well 222 having a medium surface area, and n-type well 223 having a smaller surface area. The differences in surface areas provide a gradient travel in the vertical direction and the horizontal direction, from n-type 221 to vertical transfer gate 231. In some embodiments, N-type wells 221, 222, and 223 are aligned with vertical transfer gate 231, so that vertical transfer gate 231 is centrally symmetric to each of n-type wells 221, 222, and 223. Since vertical transfer gate 213 is centrally symmetric, the diffusion distance of carriers is roughly 0.707 of the pitch size, reduced from 1.414. Moreover, the centrally symmetric vertical transfer gate can result in a more uniform transfer of charges in all directions on the surface area. As a result, the shorter or more uniformed diffusion distance provides enhanced carrier transfers from each of n-type wells 221, 222, and 223 in response to the incoming light hitting image sensor 200 (e.g., from top or from bottom onto n-type wells 221, 222, and 223). In some embodiments, a gradient doping can be applied to n-type wells 221, 222, and 223. For example, n-type well 223 comprises a lower dose, n-type well 222 comprises a medium dose, and n-type well 221 comprises a higher dose. In some embodiments, image sensor 200 can comprise other numbers of n-type wells of different dosages, such as two n-type wells or four n-type wells. The gradient doping across different n-type wells can further improve charge transfer efficiency in the vertical direction and the horizontal direction.

In some embodiments, the number of n-type wells (e.g., n-type wells 221, 222, and 223) can be considered as parts of a photodiode region configured to accumulate and transfer photogenerated image charges in response to the incoming light. A top surface of the photodiode region (e.g., the top surface of n-type well 223) is larger than a bottom surface of the photodiode region (e.g., the bottom surface of n-type well 221), so as to create a vertical gradient travel of the charges in the vertical direction. Moreover, the photodiode region can comprise at least two different doping concentrations. For example, n-type well 223 comprises a lower dose, n-type well 222 comprises a medium dose, and n-type well 221 comprises a higher dose. The gradient doping across different n-type wells can further improve charge transfer efficiency in a vertical direction.

It is appreciated that image sensor 200 shown in FIG. 2 has n-type wells in a p-type substrate. A person skilled in the art can appreciate that image sensor 200 can have p-type wells in an n-type substrate instead. For purposes of simplicity, image sensor 200 is demonstrated as having n-type wells, unless otherwise stated.

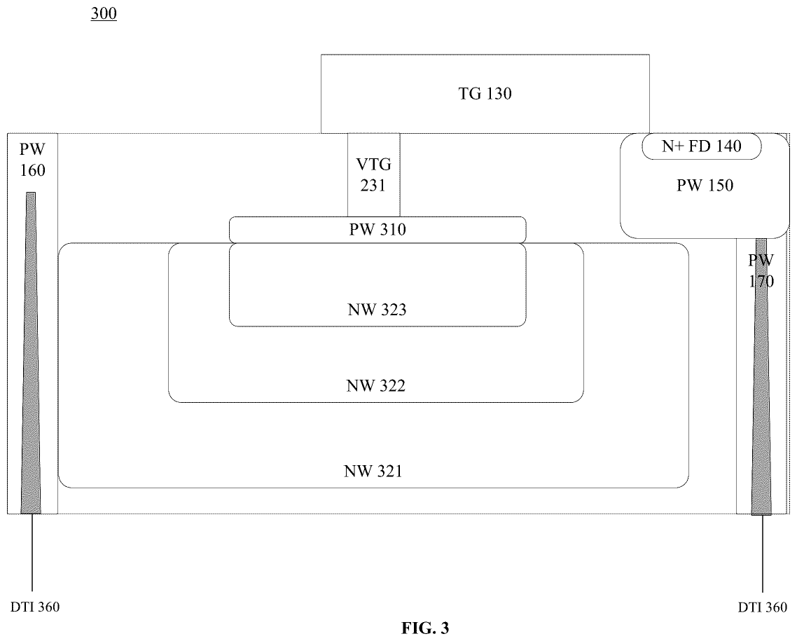

In some embodiments, in addition to gradient doping in the vertical direction, n-type wells can be implemented to provide a gradient doping in the horizontal direction. FIG. 3 is a schematic of an example image sensor with a centrally symmetric vertical transfer gate and horizontal gradient doping, according to some embodiments of this specification. The schematic in FIG. 3 is for illustrative purposes only, and image sensor 300 shown in FIG. 3 may have fewer, more, and alternative components and connections depending on the implementation.

Similar to image sensor 200, image sensor 300 comprises transfer gate 130, N+ floating diffusion node 140, p-type well 150, and vertical transfer gate 231. In addition, image sensor 300 further comprises an n-type well 321, an n-type well 322, and an n-type well 323 located under vertical transfer gate 231. In some embodiments, n-type wells 321, 322, and 323 are formed in a semiconductor substrate (e.g., p-type substrate). In some embodiments, vertical transfer gate 231 is located at or near the center of the pixel of image sensor 300 (e.g., centrally symmetric to the pixel of image sensor 300). In some embodiments, image sensor 300 further comprises a p-type well 310 located between vertical transfer gate 231 and n-type well 323. P-type well 310 can reduce dark currents generated in vertical transfer gate 231. In some embodiments, as shown in FIG. 3, p-type well 310 spans across a length of n-type well 323. In some embodiments, p-type well 310 is similar to p-type well 210 in image sensor 200. In some embodiments, p-type well 310 can span across a different length, such as a length of n-type well 321.

In some embodiments, n-type wells 321, 322, and 323 can be considered as parts of a photodiode region configured to accumulate and transfer photogenerated image charges in response to the incoming light. A top surface of the photodiode region includes top surfaces of n-type wells 321, 322, and 323. Surface areas (e.g., the top surfaces) of each of n-type wells 321, 322, and 323 are different. For example, as shown in FIG. 3, n-type well 321 has a larger surface area, n-type well 322 has a medium surface area, and n-type well 323 has a smaller surface area. As shown in FIG. 3, the top surface area of n-type well 323 is surrounded by the top surface area of n-type well 322, which is surrounded by the top surface area of n-type well 321. Moreover, depth of each of n-type wells 321, 322, and 323 are different. For example, as shown in FIG. 3, n-type well 321 encroaches below the top surface of the photodiode region at a smaller depth, n-type well 322 encroaches below the top surface of the photodiode region at a medium depth, and n-type well 323 encroaches below the top surface of the photodiode region at a larger depth. In addition, doping concentration of each of n-type wells 321, 322, and 323 are different. For example, as shown in FIG. 3, n-type well 321 has a higher dose, n-type well 322 has a medium dose, and n-type well 323 has a lower dose. The differences in surface areas, depths, and doping concentrations provide a gradient travel of charges in the vertical direction and in the horizontal direction, from n-type 321 to vertical transfer gate 231. In some embodiments, N-type wells 321, 322, and 323 are aligned with vertical transfer gate 231, so that vertical transfer gate 231 is centrally symmetric to each of N-type wells 321, 322, and 323. Since vertical transfer gate 213 is centrally symmetric, the diffusion distance of carriers is roughly 0.707 of the pitch size, reduced from 1.414. Moreover, the centrally symmetric vertical transfer gate provide a more uniform transfer of charges in all directions on the surface areas. As a result, the shorter and more uniform diffusion distance provides enhanced carrier transfers from each of n-type wells 321, 322, and 323 in response to the incoming light hitting image sensor 300 (e.g., from top or from bottom onto n-type wells 321, 322, and 323).

In some embodiments, image sensor 300 further comprises one or more deep trench isolations (DTIs) 360. For example, as shown in FIG. 3, DTIs can be located in p-type wells 160 and 170. When used in image sensors, DTIs can make photodiodes taller, which can increase capacity per area and increasing an overall effectiveness of the image sensors in capturing incoming light. For example, for Si-based photodiodes, DTI can be filled with lower refractive index materials, effectively blocking the electrical crosstalk in deep quasi-neutral region and optical crosstalk through the active Si layers. DTIs can be especially useful for back-illuminated or backside illumination (BSI) CMOS image sensors. BSI sensors can allow wirings and matrix of the sensors to be placed behind the photodiode layer away from the incoming lights, so that the incoming lights can strike the photodiode layer without passing through the wirings and the matrix. Since the wirings and the matrix are not in the way, the BSI sensors can improve an amount of the incoming lights being captured by the photodiode layer. For example, as shown in FIG. 3, incoming lights can strike from the bottom direction.

It is appreciated that image sensor 300 shown in FIG. 3 has n-type wells in a p-type substrate. A person skilled in the art can appreciate that image sensor 300 can have p-type wells in an n-type substrate instead. For purposes of simplicity, image sensor 300 is demonstrated as having n-type wells, unless otherwise stated.

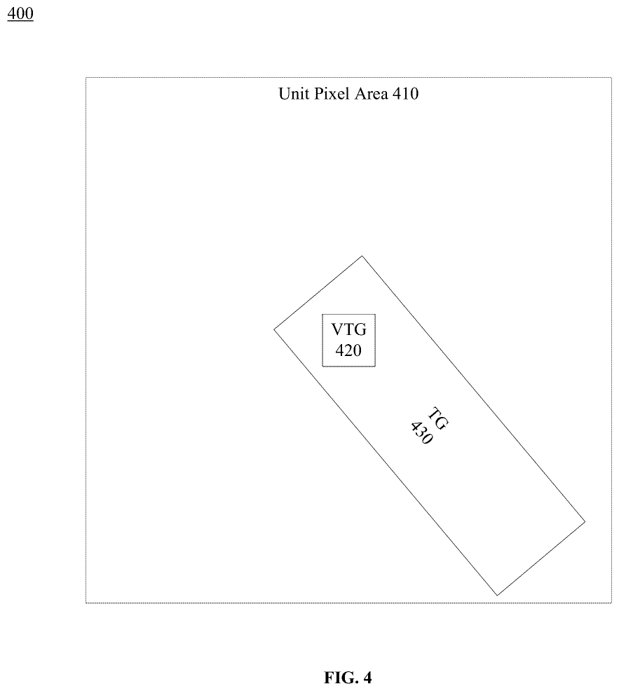

FIG. 4 is a schematic of an example image sensor with a centrally symmetric vertical transfer gate showing from a top view, according to some embodiments of this specification. The schematic in FIG. 4 is for illustrative purposes only, and image sensor 400 shown in FIG. 4 may have fewer, more, and alternative components and connections depending on the implementation.

In some embodiments, the top view of image sensor 400 shown in FIG. 4 is a top view of image sensor 200 shown in FIG. 2 or image sensor 300 shown in FIG. 3. As shown in FIG. 4, image sensor 400 comprises a unit pixel area 410, which includes a vertical transfer gate 420 and a transfer gate 430. Vertical transfer gate 420 is located at or near a center of unit pixel area 410 (e.g., centrally symmetric to unit pixel area 410). In some embodiments, vertical transfer gate 420 is similar to vertical transfer gate 231 shown in FIG. 2 or FIG. 3. In some embodiments, transfer gate 430 is similar to transfer gate 130 shown in FIG. 2 or FIG. 3. In some embodiments, n-type wells of image sensor 400 are aligned with vertical transfer gate 420, so that vertical transfer gate 420 is centrally symmetric to each of the n-type wells. Since vertical transfer gate 420 is centrally symmetric, the diffusion distance of carriers is roughly 0.707 of the pitch size of unit pixel area 410, reduced from 1.414. Moreover, the centrally symmetric vertical transfer gate provide a more uniform transfer of charges in all directions on the surface areas. As a result, the shorter and more uniform diffusion distance provides enhanced carrier transfers from each of n-type wells in response to the incoming light hitting image sensor 400 (e.g., from top or from bottom).

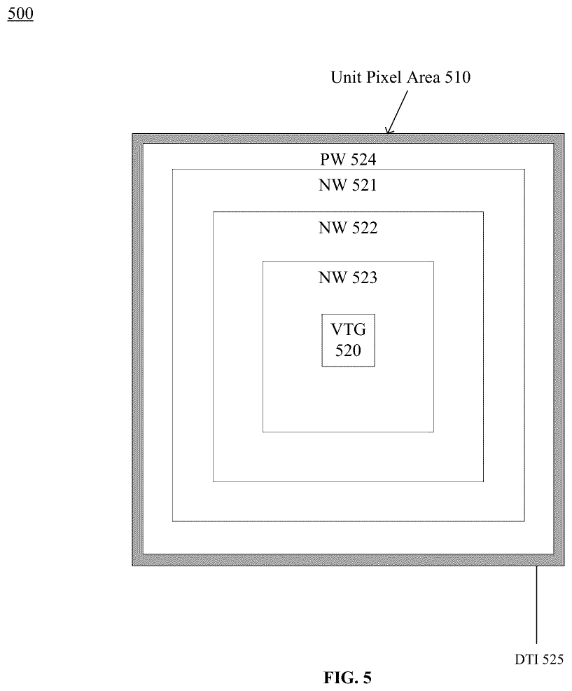

FIG. 5 is a schematic of an example image sensor with a centrally symmetric vertical transfer gate and n-type wells showing from a top view, according to some embodiments of this specification. The schematic in FIG. 5 is for illustrative purposes only, and image sensor 500 shown in FIG. 5 may have fewer, more, and alternative components and connections depending on the implementation.

In some embodiments, the top view of image sensor 500 shown in FIG. 5 is a top view of image sensor 200 shown in FIG. 2 or image sensor 300 shown in FIG. 3. As shown in FIG. 5, image sensor 500 comprises a unit pixel area 510, which includes a vertical transfer gate 520. Vertical transfer gate 520 is located at or near a center of unit pixel area 510 (e.g., centrally symmetric to unit pixel area 510). In some embodiments, vertical transfer gate 520 is similar to vertical transfer gate 231 shown in FIG. 2 or FIG. 3. Image sensor 500 further includes a number of n-type wells. For example, as shown in FIG. 5, image sensor 500 comprises n-type wells 521, 522, and 523. In some embodiments, n-type wells 521, 522, and 523 can be similar to n-type wells 221, 222, and 223 shown in FIG. 2, or n-type wells 321, 322, and 323 shown in FIG. 3. In some embodiments, n-type wells 521, 522, and 523 of image sensor 500 are aligned with vertical transfer gate 520, so that vertical transfer gate 520 is centrally symmetric to each of the n-type wells. Since vertical transfer gate 520 is centrally symmetric, the diffusion distance of carriers is roughly 0.707 of the pitch size of unit pixel area 510, reduced from 1.414. Moreover, the centrally symmetric vertical transfer gate can result in a more uniform transfer of charges in all directions on the surface areas. As a result, the shorter and more uniform diffusion distance provides enhanced carrier transfers from each of n-type wells in response to the incoming light hitting image sensor 500 (e.g., from top or from bottom).

In some embodiments, n-type wells 521, 522, and 523 can be considered as parts of a photodiode region configured to accumulate and transfer photogenerated image charges in response to the incoming light. For example, similar to image sensor 200, a top surface of the photodiode region (e.g., the top surface of n-type well 223) is larger than a bottom surface of the photodiode region (e.g., the bottom surface of n-type well 221), so as to create a vertical gradient travel of the charges in the vertical direction. In another example, similar to image sensor 300, a top surface of the photodiode region includes top surfaces of n-type wells 321, 322, and 323, and surface areas (e.g., the top surfaces) of each of n-type wells 321, 322, and 323 are different. In some embodiments, a largest surface of the photodiode region should be close to unit pixel area 510, so as to capture as much incoming light hitting image sensor 500. For example, n-type well 521 has a largest surface area among n-type wells 521, 522, and 523. As a result, the surface area of n-type well can be designed to expand to cover as much of unit pixel area 510 as possible. For example, the surface area of the n-type well can be designed to expand to 60% to 90% of unit pixel area 510. In some embodiments, image sensor 500 further comprises p-type well 524. which can be similar to p-type wells 160 and 170 shown in FIG. 2 and FIG. 3. In some embodiments, image sensor 500 further comprises DTI 525, which can be similar to DTIs 360 shown in FIG. 3.

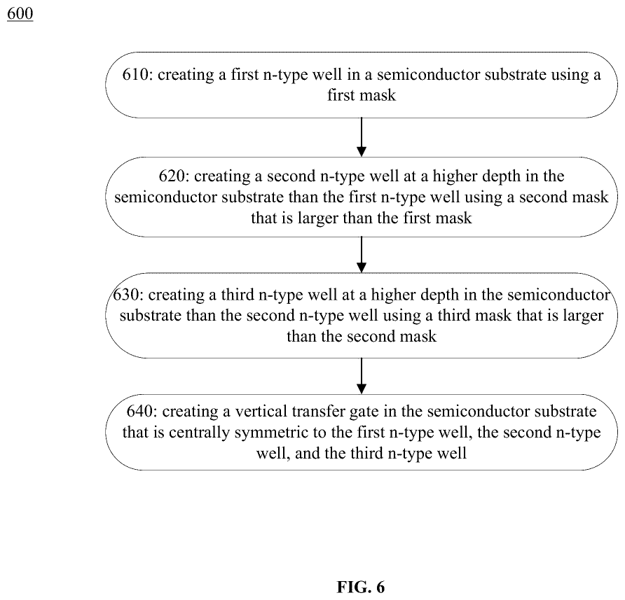

Embodiments of this specification provide methods for manufacturing image sensors with a vertical transfer gate that is symmetric to photodiode regions. FIG. 6 is a flowchart of an example method for manufacturing an image sensor with a symmetric vertical transfer gate, according to some embodiments of this specification. Method 600 may be implemented to manufacture image sensor 200 shown in FIG. 2. Depending on the implementation, method 600 may include additional, fewer, or alternative steps performed in various orders or parallel.

Step 610 includes creating a first n-type well in a semiconductor substrate using a first mask. In some embodiments, the semiconductor substrate is a part of the image sensor (e.g., image sensor 200 of FIG. 2). In some embodiments, the first n-type well is created using a photolithography process through the use of the first mask. In some embodiments, the first n-type well is similar to n-type well 221 of FIG. 2. For example, n-type well 221 is at a depth in the substrate that is deeper than other n-type wells (e.g., n-type wells 222 and 223). In some embodiments, as shown in FIG. 2, n-type well 221 has a lower dose than other n-type wells (e.g., n-type wells 222 and 223). In some embodiments, the first n-type well includes photodiode material configured to enable flowing of photogenerated charges (e.g., electrons) when the incoming light hits the image sensor. In some embodiments, a surface area of the first n-type well should be close to unit pixel area (e.g., unit pixel area 510 of FIG. 5), so as to capture as much incoming light hitting the image sensor. For example, as shown in FIG. 5, the surface area of n-type well 521 can be designed to expand to cover as much of unit pixel area 510 as possible.

Step 620 includes creating a second n-type well in the semiconductor substrate using a second mask. In some embodiments, the second n-type well is created using a photolithography process through the use of the second mask. In some embodiments, the second n-type well is similar to n-type well 222 of FIG. 2. For example, n-type well 222 is at a depth in the substrate that is in a middle of other n-type wells (e.g., n-type wells 221 and 223). In some embodiments, as shown in FIG. 2, n-type well 222 has a medium dose compared with other n-type wells (e.g., n-type wells 221 and 223). In some embodiments, the second n-type well has a surface area that is smaller than the first n-type well. For example, as shown in FIG. 2, the surface area of n-type well 222 is smaller than the surface area of n-type well 221. As a result, the second mask can have a surface area that is smaller than the first mask. In some embodiments, the second n-type well is centrally symmetric with the first n-type well. For example, as shown in FIG. 5, n-type well 522 is centrally symmetric with n-type well 521 when viewed from above or below.

Step 630 includes creating a third n-type well in the semiconductor substrate using a third mask. In some embodiments, the third n-type well is created using a photolithography process through the use of the third mask. In some embodiments, the third n-type well is similar to n-type well 223 of FIG. 2. For example, n-type well 223 is at a depth in the substrate that is shallower than other n-type wells (e.g., n-type wells 221 and 222). In some embodiments, as shown in FIG. 2, n-type well 223 has a medium dose compared with other n-type wells (e.g., n-type wells 221 and 222). In some embodiments, the third n-type well has a surface area that is smaller than the second n-type well. For example, as shown in FIG. 2, the surface area of n-type well 223 is smaller than the surface area of n-type well 222. As a result, the third mask can have a surface area that is smaller than the second mask. In some embodiments, the third n-type well is centrally symmetric with the first n-type well and the second n-type well. For example, as shown in FIG. 5, n-type well 523 is centrally symmetric with n-type well 521 and n-type well 522 when viewed from above or below.

Step 640 includes creating a vertical transfer gate in the semiconductor substrate. In some embodiments, the vertical transfer gate is similar to vertical transfer gate 231 shown in FIG. 2 or vertical transfer gate 420 shown in FIG. 4 or FIG. 5. In some embodiments, the vertical transfer gate encroaches into the semiconductor substrate. In some embodiments, the vertical transfer gate is centrally symmetric with the first n-type well, the second n-type well, and the third n-type well. For example, as shown in FIG. 5, vertical transfer gate 420 is centrally symmetric with n-type well 521, n-type well 522, and n-type well 523 when viewed from above or below.

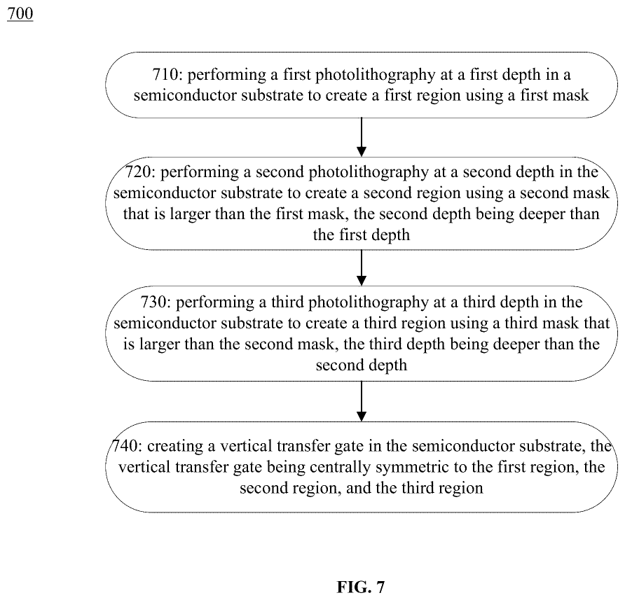

FIG. 7 is a flowchart of an example method for manufacturing an image sensor with a symmetric vertical transfer gate, according to some embodiments of this specification. Method 700 may be implemented to manufacture image sensor 300 shown in FIG. 3. Depending on the implementation, method 700 may include additional, fewer, or alternative steps performed in various orders or parallel.

Step 710 includes performing a first photolithography at a first depth in a semiconductor substrate using a first mask. In some embodiments, the semiconductor substrate is a part of the image sensor (e.g., image sensor 300 of FIG. 3). The first photolithography performed in step 710 creates a first region that is similar to the first n-type well is similar to n-type well 323 of FIG. 3. For example, n-type well 323 shares a same top surface with other n-type wells (e.g., n-type wells 321 and 322) and n-type well 323 has a top surface that is smaller than the top surfaces of other n-type wells. In some embodiments, the first n-type well includes photodiode material configured to enable flowing of photogenerated charges (e.g., electrons) when the incoming light hits the image sensor.

Step 720 includes performing a second photolithography at a second depth in the semiconductor substrate using a second mask. In some embodiments, the second photolithography performed in step 720 creates a second region that is similar to n-type well 322 of FIG. 3. In some embodiments, the second depth is deeper than the first depth, the second mask is larger than the first mask, and the first region and the second region share a same top surface. For example, as shown in FIG. 3, the top surface of n-type well 323 is surrounded by the top surface of n-type well 322. In some embodiments, the second lithography also causes the first region to have a dosage concentration that is higher than the dosage concentration of the second region, since the first region undergoes the first lithography and the second lithography. For example, as shown in FIG. 3, n-type well 322 has a medium dose compared with the higher dose of n-type well 323. In some embodiments, the second region is centrally symmetric with the first region. For example, as shown in FIG. 5, n-type well 522 is centrally symmetric with n-type well 521 when viewed from above or below.

Step 730 includes performing a third photolithography at a third depth in the semiconductor substrate using a third mask. In some embodiments, the third photolithography performed in step 730 creates a third region that is similar to n-type well 321 of FIG. 3. In some embodiments, the third depth is deeper than the second depth, the third mask is larger than the second mask, and the first region the second region and the third region share the same top surface. For example, as shown in FIG. 3, the top surface of n-type well 322 is surrounded by the top surface of n-type well 321. In some embodiments, the second lithography also causes the first region to have a dosage concentration that is higher than the dosage concentration of the second region and the dosage concentration of the second region to be higher than the dosage concentration of the third region, since the first region undergoes the first lithography, the second lithography, and the third lithography, and the second region undergoes the second lithography and the third lithography. For example, as shown in FIG. 3, n-type well 321 has a lower dose compared with the medium dose of n-type well 322 and the higher dose of n-type well 323. In some embodiments, the third region is centrally symmetric with the first region and the second region. For example, as shown in FIG. 5, n-type well 523 is centrally symmetric with n-type well 521 and n-type well 522 when viewed from above or below. In some embodiments, a surface area of the third region should be close to unit pixel area (e.g., unit pixel area 510 of FIG. 5), so as to capture as much incoming light hitting the image sensor. For example, as shown in FIG. 5, the surface area of n-type well 521 can be designed to expand to cover as much of unit pixel area 510 as possible.

Step 740 includes creating a vertical transfer gate in the semiconductor substrate. In some embodiments, the vertical transfer gate is similar to vertical transfer gate 231 shown in FIG. 3 or vertical transfer gate 420 shown in FIG. 4 or FIG. 5. In some embodiments, the vertical transfer gate is centrally symmetric with the first region, the second region, and the third region. For example, as shown in FIG. 5, vertical transfer gate 420 is centrally symmetric with n-type well 521, n-type well 522, and n-type well 523 when viewed from above or below.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuit.

When the functions disclosed herein are implemented in the form of software functional units and sold or used as independent products, they can be stored in a processor executable non-volatile computer-readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, where the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain methods or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of example methods described herein may be performed, at least partially, by an algorithm. The algorithm may be comprised in program codes or instructions stored in a memory (e.g., a non-transitory computer-readable storage medium described above). Such algorithm may comprise a machine learning algorithm. In some embodiments, a machine learning algorithm may not explicitly program computers to perform a function but can learn from training data to make a prediction model that performs the function.

The various operations of example methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or sections of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. An integrated circuit, comprising:
a photodiode region disposed in a substrate, wherein:
the photodiode region is configured to accumulate charge photogenerated in the photodiode region in response to incoming light,
the photodiode region comprises a top surface and a bottom surface, the top surface being smaller than the bottom surface,
the photodiode region comprises at least two doping concentrations, and
a first doping concentration of the two doping concentrations that is closer to the top surface is higher than a second doping concentration of the two doping concentrations that is closer to the bottom surface; and
a vertical transfer gate in the substrate, wherein:
the vertical transfer gate is above the top surface of the photodiode region and is centrally symmetric to the top surface of the photodiode region, and
the vertical transfer gate is configured to transfer the photogenerated charge from the photodiode region to a transfer gate.

2. The integrated circuit of claim 1, wherein the vertical transfer gate is centrally symmetric to the bottom surface of the photodiode region.

3. The integrated circuit of claim 1, wherein:
the photodiode region comprises a first well and a second well,
the first well is closer to the top surface of the photodiode region than the second well,
the first well has the first doping concentration, and
the second well has the second doping concentration.

4. The integrated circuit of claim 3, wherein:
the photodiode region comprises a third well,
the third well is closer to the bottom surface of the photodiode region than the first well and the second well,
the third well has a third doping concentration, and
the third doping concentration is lower than the first doping concentration and the second doping concentration.

5. The integrated circuit of claim 1, wherein:
the integrated circuit is an image sensor that includes a pixel, and
the bottom surface of the photodiode region is configured to expand to 90% of a unit pixel area of the pixel.

6. The integrated circuit of claim 5, wherein the vertical transfer gate is centrally symmetric to the unit pixel area of the pixel.

7. The integrated circuit of claim 1, wherein the substrate is a p-type substrate, and the photodiode region is an n-type region.

8. The integrated circuit of claim 7, further comprising a p-type well formed between the top surface of the photodiode region and the vertical transfer gate.

9. The integrated circuit of claim 1, wherein the vertical transfer gate is further configured to transfer the photogenerated charge from the photodiode region to the transfer gate located outside of the substrate.

10. An integrated circuit, comprising:
a photodiode region disposed in a substrate, wherein:
the photodiode region is configured to accumulate charge photogenerated in the photodiode region in response to incoming light,
the photodiode region comprises a top surface, a first well, and a second well,
the top surface of the photodiode region comprises a top surface of the first well and a top surface of the second well,
the top surface of the first well is surrounded by the top surface of the second well,
the second well has a depth that is deeper than a depth of the first well, and
the first well has a first doping concentration that is higher than a second doping concentration of the second well; and
a vertical transfer gate in the substrate, wherein:
the vertical transfer gate is above the top surface of the photodiode region and is centrally symmetric to the top surface of the first well, and
the vertical transfer gate is configured to transfer the photogenerated charge from the photodiode region to a transfer gate.

11. The integrated circuit of claim 10, wherein the vertical transfer gate is centrally symmetric to the top surface of the second well.

12. The integrated circuit of claim 10, wherein:
the photodiode region comprises a third well,
the top surface of the photodiode region comprises a top surface of the third well,
the top surface of the second well is surrounded by the top surface of the third well,
the third well has a depth that is deeper than the depth of the second well, and
the third well has a third doping concentration that is lower than the second doping concentration.

13. The integrated circuit of claim 12, wherein the vertical transfer gate is centrally symmetric to the top surface of the third well.

14. The integrated circuit of claim 12, wherein:
the integrated circuit is an image sensor that includes a pixel, and
the top surface of the third well is configured to expand to 90% of a unit pixel area of the pixel.

15. The integrated circuit of claim 14, wherein the vertical transfer gate is centrally symmetric to the unit pixel area of the pixel.

16. The integrated circuit of claim 10, wherein the substrate is a p-type substrate, and the photodiode region is an n-type region.

17. The integrated circuit of claim 16, further comprising a p-type well formed between the top surface of the photodiode region and the vertical transfer gate.

18. The integrated circuit of claim 10, wherein the vertical transfer gate is further configured to transfer the photogenerated image charge from the photodiode region to a transfer gate located outside the substrate.

19. A method for manufacturing an integrated circuit, comprising:
creating a first well in a substrate of the integrated circuit using a first mask at a first depth into the substrate;
creating a second well in the substrate using a second mask at a second depth into the substrate, wherein the second mask comprises a surface area that is smaller than a surface area of the first mask, and the second depth is shallower than the first depth; and
creating a vertical transfer gate itched into the substrate, wherein the vertical transfer gate is centrally symmetric to a top surface of the first well and a top surface of the second well, and the vertical transfer gate is configured to transfer charge photogenerated in the first well and the second well in response to incoming light.

20. The method of claim 19, further comprising:
creating a third well in the substrate using a third mask at a third depth into the substrate, wherein the third mask comprises a surface area that is smaller than the surface area of the second mask, and the third depth is shallower than the second depth.
